(19) United States
(12) Patent Application Publication
(10) Pub. No.: US 2014/0048326 A1
(43) Pub. Date: Feb. 20, 2014

(54) MULTI-CAVITY WIRING BOARD FOR SEMICONDUCTOR ASSEMBLY WITH INTERNAL ELECTROMAGNETIC SHIELDING

(71) Applicant: Bridge Semiconductor Corporation, Taipei City (TW)

(72) Inventors: Charles W.C. LIN, Singapore (SG); Chia-Chung WANG, Hsinchu (TW)

(73) Assignee: Bridge Semiconductor Corporation, Taipei City (TW)

(21) Appl. No.: 13/962,991

(22) Filed: Aug. 9, 2013

Related U.S. Application Data
(63) Continuation-in-part of application No. 13/615,819, filed on Sep. 14, 2012.
Application No. 13/615,819 is a continuation-in-part of application No. 13/753,625, filed on Jan. 30, 2013.
Application No. 13/753,625 is a continuation-in-part of application No. 13/733,226, filed on Jan. 3, 2013.
Application No. 13/753,625 is a continuation-in-part of application No. 13/615,819, filed on Sep. 14, 2012.
(60) Provisional application No. 61/731,564, filed on Nov. 30, 2012.
(60) Provisional application No. 61/682,801, filed on Aug. 14, 2012.
(60) Provisional application No. 61/682,801, filed on Aug. 14, 2012.
(60) Provisional application No. 61/682,801, filed on Aug. 14, 2012.

(51) Int. Cl. H05K 9/00

(52) U.S. Cl. CPC H05K 9/00
USPC 174/377

(57) ABSTRACT

A multi-cavity wiring board includes a coreless substrate, an adhesive, and a stiffener having a plurality of apertures with lateral shielding sidewalls. The coreless substrate covers the stiffener and includes electrical pads exposed from the apertures of the stiffener as electrical contacts for semiconductor devices packaged within the apertures. The aperture sidewalls of the stiffener can serve as effective lateral electromagnetic shields for the semiconductor devices within the apertures.

### CROSS REFERENCE TO RELATED APPLICATION

This application is a continuation-in-part of U.S. application Ser. No. 13/615,819 filed Sep. 14, 2012, a continuation-in-part of U.S. application Ser. No. 13/753,625 filed Jan. 30, 2013 and a continuation-in-part of U.S. application Ser. No. 13/733,226 filed Jan. 3, 2013, each of which is incorporated by reference. This application also claims the benefit of filing date of U.S. Provisional Application Ser. No. 61/731,564 filed Nov. 30, 2012.

U.S. application Ser. No. 13/753,625 filed Jan. 30, 2013 is a continuation-in-part of U.S. application Ser. No. 13/615,819 filed Sep. 14, 2012. U.S. application Ser. No. 13/615,819 filed Sep. 14, 2012, U.S. application Ser. No. 13/753,625 filed Jan. 30, 2013 and U.S. application Ser. No. 13/733,226 filed Jan. 3, 2013 all claim the benefit of filing date of U.S. Provisional Application Ser. No. 61/682,801 filed Aug. 14, 2012.

### BACKGROUND OF THE INVENTION

1. Field of the Invention

The present invention relates to a multi-cavity wiring board for a semiconductor assembly with electromagnetic shielding, and more particularly to a multi-cavity wiring board that includes a plurality of cavities with lateral shielding sidewalls.

2. Description of Related Art

The semiconductor devices are susceptible to electromagnetic interference (EMI) or other inter-device interference, such as capacitive, inductive, conductive coupling when operated in a high frequency mode. These undesirable interferences may become increasingly serious when the semiconductor dies are placed closely together for the miniaturization purpose. Conventional approaches to isolate these devices include forming a conductive layer on the encapsulant or placing a metal cover over an assembly. For multi-chip assembly, however, the shielding must be formed over the individual semiconductor die prior to final encapsulation in order to reduce the interference between the semiconductor dies on a board.

U.S. Pat. No. 7,187,060 to Usui, U.S. Pat. No. 8,076,757 to Pagalla et al., and U.S. Pat. No. 8,093,691 to Fuentes et al., disclose various semiconductor devices in which a conductive layer is applied to a sealant or mold compound for EMI shielding after the semiconductor die is encapsulated. None of these approaches offers a proper EMI shielding or effective electromagnetic protection at the wiring board level especially when the semiconductor dies are disposed side-by-side on a board.

### SUMMARY OF THE INVENTION

The present invention has been developed in view of such a situation, and an object thereof is to provide a wiring board having a plurality of cavities with lateral shielding sidewalls which can serve as effective lateral electromagnetic shields for semiconductor devices packaged in the cavities and therefore is suitable for multi-chip package with minimized internal electromagnetic interference (EMI). Accordingly, the present invention provides a multi-cavity wiring board that includes a coreless substrate, an adhesive, and a stiffener having a plurality of apertures with lateral shielding sidewalls.

In a preferred embodiment, the stiffener includes multiple apertures with electrically conductive sidewalls and is affixed on the coreless substrate using the adhesive that contacts and is sandwiched between the stiffener and the coreless substrate. The stiffener can extend to peripheral edges of the wiring board and provide mechanical support to suppress warp and bend of the wiring board. The stiffener can be a single or multi-layer structure with embedded single-level conductive traces or multi-level conductive traces, such as multi-layer circuit board. The stiffener can be made of nonmetallic materials, such as various inorganic or organic insulating materials including ceramics, aluminum oxide (Al₂O₃), aluminum nitride (AlN), silicon nitride (SiN), silicon (Si), glass, laminated epoxy, polyamide or copper-clad laminate. By a plating process, the apertures of the nonmetallic stiffener can be formed with metallized sidewalls that can serve as lateral EMI shields for semiconductor devices within the apertures. The stiffener can also be made of metal, such as copper (Cu), aluminum (Al), stainless steel, etc.

The coreless substrate covers the stiffener in the first vertical direction and includes electrical pads and a build-up circuitry. The electrical pads are aligned with and exposed from the apertures of the stiffener in the second vertical direction. The build-up circuitry covers the electrical pads and the stiffener in the first vertical direction and is electrically connected to the electrical pads through first conductive vias. The build-up circuitry can include a first dielectric layer, first via openings and one or more first conductive traces. For instance, the first dielectric layer covers the electrical pads and the stiffener in the first vertical direction and can extend to peripheral edges of the wiring board, and the first conductive traces extend from the first dielectric layer in the first vertical direction. The first via openings in the first dielectric layer are aligned with the electrical pads. One or more first conductive traces extend from the first dielectric layer in the first vertical direction, extend laterally on the first dielectric layer, and extend through the first via openings in the second vertical direction to form the first conductive vias in electrical contact with the electrical pads, thereby providing signal routing for the electrical pads through the first conductive vias. Further, the build-up circuitry can provide an electrical connection between the stiffener and a portion of the electrical pads for ground connection purpose. For instance, the first conductive traces can extend into additional first via openings of the first dielectric layer in the second vertical direction to form one or more additional first conductive vias in electrical contact with a metallized first surface of the stiffener that faces the first vertical direction. The metal layer at the first surface of the stiffener is adjacent to and electrically connected to the metal layer of the metallized apertures. Accordingly, the stiffener can be electrically connected to the build-up circuitry through the additional first conductive vias, and the first conductive traces can provide an electrical connection between the lateral shielding sidewalls of the stiffener and a portion of the electrical pads for ground connection. Alternatively, one or more plated through holes can extend through the stiffener to provide an electrical connection between the stiffener and the build-up circuitry. For instance, the plated though hole at a first end can extend to and be electrically connected to an outer or inner conductive layer of the build-up circuitry and at a second end can extend to and be electrically connected to a metallized second surface of the stiffener that faces the second vertical direction. The metal layer at the second surface of the stiffener is adjacent to and electrically connected to the metal layer of the metallized apertures. As a result, the ground connection for the lateral shielding sidewalls can be provided by the plated through hole and the conductive traces of the build-up circuitry. In any case, the electrical connection between the electrical pad and the lateral shielding sidewalls of the stiffener can provided by the build-up circuitry and is favorable for effective lateral EMI shielding effect.

The build-up circuitry can include additional layers of dielectric, additional layers of via openings, and additional layers of conductive traces if needed for further signal routing. For instance, the build-up circuitry can further include a second dielectric layer, one or more second via openings and one or more second conductive traces. The second dielectric layer with one or more second via openings extends from the first dielectric layer and the first conductive traces in the first vertical direction and extends to peripheral edges of the wiring board. The second via openings are disposed adjacent to the first conductive traces. One or more second conductive traces extend from the second dielectric layer in the first vertical direction and extend laterally on the second dielectric layer and extend into the second via openings in the second vertical direction to provide electrical connections for the first conductive traces. The first via openings and the second via openings can have the same size, and the first dielectric layer, the first conductive traces, the second dielectric layer and the second conductive traces can have flat elongated surfaces that face in the first vertical direction.

The outmost conductive traces of the build-up circuitries can include one or more terminal pads to provide electrical contacts for an electronic device such as a semiconductor chip, a plastic package or another semiconductor assembly. The terminal pads can include an exposed contact surface that faces in the first vertical direction. As a result, the wiring board can include electrical contacts (i.e. the terminal pads and the electrical pads) that are electrically connected to one another and located on opposite surfaces that face in opposite vertical directions, so that the wiring board is stackable and electronic devices can be electrically connected to the wiring board using a wide variety of connection media including wire bonding or solder bumps as the electrical contacts.

The coreless substrate of the wiring board can further include one or more thermal paddles that are covered by the build-up circuitry in the first vertical direction and are exposed from the corresponding apertures of the stiffener in the second vertical direction. The thermal paddle can be made of any thermal conductive material, such as a metal layer that extends from the build-up circuitry in the second vertical direction. The build-up circuitry can further include one or more additional first conductive vias that directly contact the thermal paddle. As a result, the heat generated by a semiconductor device mounted on the thermal paddle can be dissipated through the thermal conduction pathway of the wiring board that is provided by the thermal paddle and the conductive vias formed in the build-up circuitry. Further, the thermal paddle and the above-mentioned electrical pads can be simultaneously formed and be coplanar with one another in the first and second vertical directions.

The coreless substrate can further include a placement guide for the stiffener. The placement guide extends from the build-up circuitry in the second vertical direction and is laterally aligned with the stiffener to stop undesired displacement of the stiffener. Specifically, the placement guide can laterally extend beyond and be close proximity to the peripheral edges of the stiffener. Alternatively, the placement guide can laterally extend within the aperture and be close proximity to the aperture sidewalls of the stiffener. Likewise, the coreless substrate can further include a stopper on each thermal paddle which extends from the thermal paddle in the second vertical direction and can serve as a placement guide for a semiconductor device mounted on the thermal paddle. The placement guide and the stopper can be made of a metal, a photosensitive plastic material or non-photosensitive material, such as copper, aluminum, nickel, iron, tin, alloys, epoxy or polyimide. Further, the placement guide, the thermal paddle and the electrical pads can be simultaneously formed and be coplanar with one another in the first and second vertical directions.

The placement guide and the stopper preferably have a thickness in a range of 10-200 microns, and respectively have patterns against undesirable movement of the stiffener and the semiconductor device. For instance, the placement guide and the stopper can respectively include a continuous or discontinuous strip or an array of posts. Specifically, the placement guide can be laterally aligned with four outer peripheral edges of the stiffener or four aperture sidewalk of the stiffener to stop the lateral displacement of the stiffener. For instance, the placement guide can be aligned along and conform to four sides, two diagonal corners or four corners of the outer peripheral edges of the stiffener, and a gap in between the outer peripheral edges of the stiffener and the placement guide preferably is in a range of about 0.001 to 1 mm. Alternatively, the placement guide can be aligned along and conform to four sides, two diagonal corners or four corners of the aperture edges of the stiffener, and a gap in between the aperture sidewall of the stiffener and the placement guide preferably is in a range of about 0.001 to 1 mm. Likewise, the stopper can be designed with the same concept for the above-mentioned placement guide. For instance, the stopper can conform to four sides, two diagonal corners or four corners of a semiconductor device to be mounted on the thermal paddle. Accordingly, the semiconductor device can be precisely mounted on the thermal paddle at a predetermined location by the stopper that laterally extends beyond and is laterally aligned with and close proximity to the peripheral edges of the semiconductor device. The gap in between the stopper and the semiconductor device preferably is in a range of about 0.001 to 1 mm.

The multi-cavity wiring board of the present invention can further include an interposer that extends into the aperture of the stiffener and is electrically connected to the coreless substrate. The interposer can be a silicon, glass or ceramic interposer and includes one or more first contact pads and one or more second contact pads on two opposite surfaces thereof. The first contact pads of the interposer faces the first vertical direction and can be electrically coupled to the electrical pads using a wide variety of connection media including gold or solder bumps. The second contact pads of the interposer faces the second vertical direction and can be exposed from the aperture of the stiffener. Besides, the interposer can further include one or more connecting elements (such as through vias) that electrically connect the first contact pads and the second contact pads. As a result, the second contact pads of the interposer and the terminal pads of the build-up circuitry can be electrically connected to one another and can serve as electrical contacts located on opposite surfaces of the wring board.

The present invention also provides a semiconductor assembly in which semiconductor devices such as chips extend within the apertures of the stiffener and are electrically connected to the coreless substrate. Specifically, the semiconductor device can be flip mounted on the coreless substrate or the interposer within the aperture by solder bumps on the electrical pads of the coreless substrate or the second contact pads of the interposer. Alternatively, the semiconductor device may be mounted on the thermal paddle and electrically connected to the electrical pads by wire bonds. Accordingly, the signal contact pads of the semiconductor device can be electrically connected to the signal transduction pathways of the wiring board by signal electrical pads. The ground contact pads of the semiconductor device can be electrically connected to the lateral shielding sidewalls of the stiffener by ground electrical pads. Further, the semiconductor devices located within different apertures of the stiffener can be completely enclosed by the lateral shielding sidewalls of the stiffener in the lateral directions and be spaced from one another by the stiffener. As a result, each semiconductor device can be shielded from electromagnetic interference signals from others by the metal layer of the aperture sidewalls that completely covers peripheral edges of the semiconductor device in the lateral directions.

The present invention has numerous advantages. The stiffener can provide a mechanical support for the coreless substrate. The lateral shielding sidewalls of the stiffener can serve as lateral EMI shields for semiconductor devices within the apertures and therefore are favorable for multi-chip package with minimized internal electromagnetic interference. The electrical connection between ground electrical pads and the lateral shielding sidewalls pan be provided by the build-up circuitry, and thus effective lateral electromagnetic shielding effect can diminish the internal electromagnetic interference among semiconductor devices packaged in the wiring board. The signal routing can be provided by the build-up circuitry and is advantageous for high I/O and high performance applications due to the high routing capability of the build-up circuitry. Further, the placement location of the stiffener can be accurately confined by the placement guide to avoid the undesired lateral displacement of the stiffener, thereby improving the manufacturing yield greatly. The wiring board and the semiconductor assembly using the same are reliable, inexpensive and well-suited for high volume manufacture. These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1-8 are cross-section views showing a method of making a multi-cavity wiring board that includes a stiffener, an adhesive and a coreless substrate in accordance with an embodiment of the present invention, in which FIG. 3A is a top view corresponding to FIG. 3;

FIG. 9 is a cross-sectional view showing a semiconductor assembly that includes semiconductor devices located within metallized cavities of the wiring board and covered by a metal lid in accordance with an embodiment of the present invention;

FIG. 10 is a cross-sectional view showing another semiconductor assembly that includes semiconductor devices attached to interposers within metallized cavities of the wiring board and covered by a metal lid in accordance with an embodiment of the present invention;

FIGS. 11 and 11A are cross-sectional and top views, respectively, of another multi-cavity wiring board with plated through holes as electrical connection between metallic sidewalls of apertures and electrical pads in accordance with another embodiment of the present invention;

FIGS. 12-18 are cross-section views showing a method of making yet another multi-cavity wiring board that includes electrical pads, thermal paddles, stoppers and placement guide exposed from metallic apertures of a stiffener in accordance with yet another embodiment of the present invention, in which FIGS. 12A and 13A are top views corresponding to FIGS. 12 and 13, respectively; and

FIG. 19 is a cross-sectional view showing yet another semiconductor assembly that includes semiconductor devices mounted on thermal paddles and electrically connected to electrical pads and covered by a metal lid in accordance with yet another embodiment of the present invention.

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. It should be noted that these accompanying figures are simplified. The quantity, shape and size of components shown in the figures may be modified according to practically conditions, and the arrangement of components may be more complex. Other various aspects also may be practiced or applied in the invention, and various modifications and variations can be made without departing from the spirit of the invention based on various concepts and applications.

### Embodiment 1

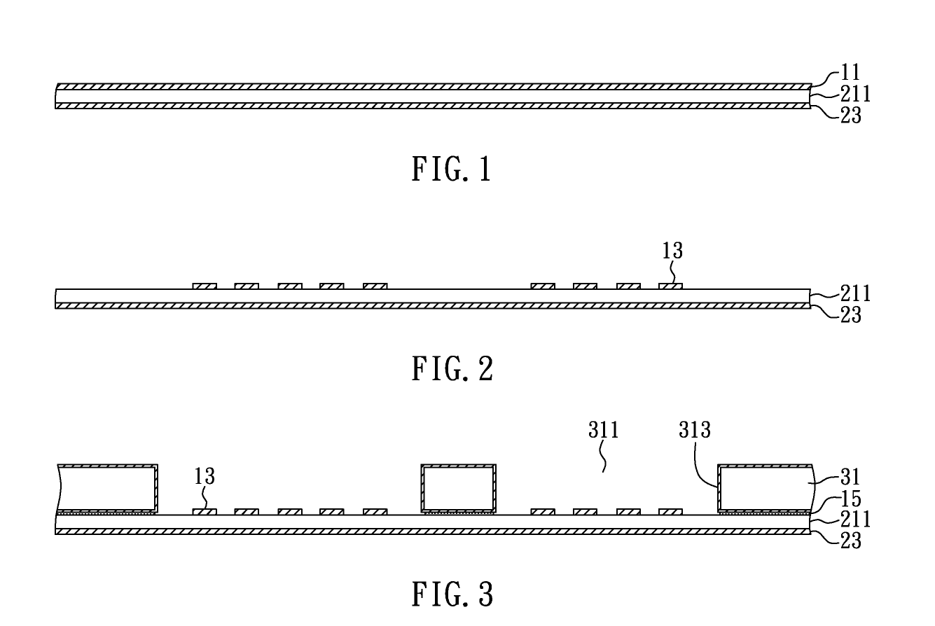

FIGS. 1-8 are cross-section views showing a method of making a multi-cavity wiring board that includes a careless substrate, an adhesive, and a stiffener having multiple apertures with lateral shielding sidewalls in accordance with an embodiment of the present invention.

As shown in FIG. 8, multi-cavity wiring board 100 includes stiffener 31, adhesive 15 and coreless substrate 201. Stiffener 31 includes multiple apertures 311 with lateral shielding sidewalls and is affixed on coreless substrate 201 using adhesive 15. In this illustration, coreless substrate 201 includes electrical pads 13, first dielectric layer 211, first conductive traces 231, second dielectric layer 251 and second conductive traces 271. First conductive traces 231 are electrically connected to electrical pads 13 for signal routing, and also provide an electrical interconnection between electrical pads 13 and stiffener 31 for grounding the lateral shielding sidewalls of apertures 311.

FIG. 1 is a cross-sectional view of a laminate substrate that includes metal layer 11, first dielectric layer 211 and support plate 23. Metal layer 11 is illustrated as a copper layer with a thickness of 35 microns. However, metal layer 11 can also be made of copper alloys or other materials. Besides, metal layer 11 can be deposited on first dielectric layer 211 by numerous techniques including lamination, electroplating, electroless plating, evaporating, sputtering, and their combinations as a single layer or multiple layers, and preferably has a thickness in a range of 5 to 200 microns.

First dielectric layer 21 typically is made of epoxy resin, glass-epoxy, polyimide and the like and has a thickness of 50 microns. In this embodiment, first dielectric layer 211 is sandwiched between metal layer 11 and support plate 23. However, support plate 23 may be omitted in some embodiments. Support plate 23 typically is made of copper, but copper alloys or other materials are also doable. The thickness of support plate 23 can range from 25 to 1000 microns, and preferably ranges from 35 to 100 microns in consideration of process and cost. In this embodiment, support plate 23 is illustrated as a copper plate with a thickness of 35 microns.

FIG. 2 is a cross-sectional view of the structure with electrical pads 13 formed on first dielectric layer 211. Electrical pads 13 can be formed by removing selected portions of metal layer 13 using photolithography and wet etching. Alternatively, in some embodiments which apply a laminate substrate without metal layer 11 on first dielectric layer 211, electrical pads 13 can be directly pattern deposited on first dielectric layer 211 by numerous techniques including electroplating, electroless plating, evaporating, sputtering and their combinations.

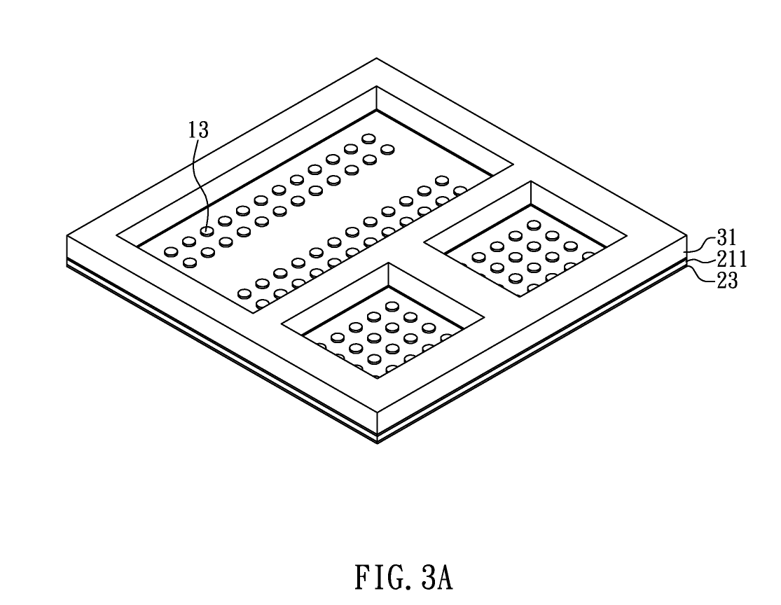

FIGS. 3 and 3A are cross-section and top views, respectively, of the structure with stiffener 31 mounted onto first dielectric layer 211. Electrical pads 13 are aligned with apertures 311 of stiffener 31, and stiffener 31 is mounted on first dielectric layer 211 using adhesive 15 that contacts and is sandwiched between stiffener 31 and first dielectric layer 211. Stiffener 31 is illustrated as a ceramic sheet with conductive layer 313 in apertures 311 as well as on top and bottom surfaces. Multiple aperture 311 are formed by laser cutting through stiffener 31 and can be formed with other techniques such as punching and mechanical drilling. Apertures 311 as well as top and bottom surfaces of stiffener 31 are metallized by plating to provide conductive layer 313 thereon. Accordingly, the metallic sidewalls of multiple apertures 311 can provide lateral EMI shielding effect for semiconductor devices mounted within apertures 311.

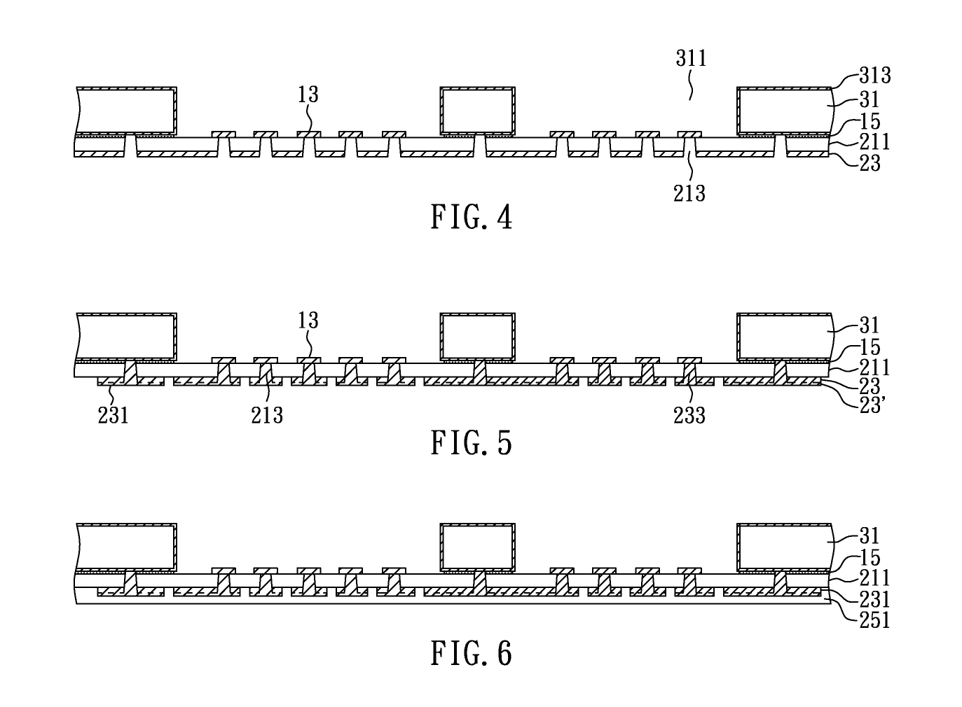

FIG. 4 is a cross-sectional view of the structure provided with first via openings 213. First via openings 213 extend through support plate 23, first dielectric layer 211 and adhesive 15 to expose selected portions of electrical pads 13 and conductive layer 313 of stiffener 31 in the downward direction. First via openings 213 may be formed by numerous techniques including laser drilling, plasma etching and photolithography, and typically have a diameter of 50 microns. Laser drilling can be enhanced by a pulsed laser. Alternatively, a scanning laser beam with a metal mask can be used. For instance, copper can be etched first to create a metal window followed by laser.

Referring now to FIG. 5, first conductive traces 231 are formed on first dielectric layer 211 by depositing plated layer 23′ on support plate 23 and into first via openings 213 and then patterning support plate 23 and plated layer 23′ thereon. Alternatively, in some embodiments which apply a laminate substrate without support plate 23, the first dielectric layer 211 can be directly metallized to form first conductive traces 231. First conductive traces 231 can provide horizontal signal routing in both the X and Y directions and vertical (top to bottom) routing through first via openings 213. Further, first conductive traces 231 also provide an electrical interconnection between conductive layer 313 of stiffener 31 and a portion of electrical pads 13 for ground connection purpose.

Plated layer 23′ can be deposited by numerous techniques including electroplating, electroless plating, evaporating, sputtering, and their combinations as a single layer or multiple layers. For instance, plated layer 23′ is deposited by first dipping the structure in an activator solution to render first dielectric layer 211 catalytic to electroless copper, then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, support plate 23 and plated layer 23′ can be patterned to form first conductive traces 231 by numerous techniques including wet etching, electro-chemical etching, laser-assist etching, and their combinations with an etch mask (not shown) thereon that defines first conductive traces 231. Accordingly, first conductive traces 231 extend from first dielectric layer 211 in the downward direction, extend laterally on first dielectric layer 211 and extend into first via openings 213 in the upward direction to form first conductive vias 233 in electrical contact with electrical pads 13 and conductive layer 313 of stiffener 31.

Support plate 23 and plated layer 23′ thereon are shown as a single layer for convenience of illustration. The boundary (shown in phantom) between the metal layers may be difficult or impossible to detect since copper is plated on copper. However, the boundary between plated layer 23′ and first dielectric layer 211 is clear.

FIG. 6 is a cross-sectional view of the structure showing second dielectric layer 251 disposed on first conductive traces 231 and first dielectric layer 211. Second dielectric layer 251 can be epoxy resin, glass-epoxy, polyimide and the like deposited by numerous techniques including film lamination, spin coating, roll coating, and spray-on deposition and typically has a thickness of 50 microns. Preferably, first dielectric layer 211 and second dielectric layer 251 are the same material.

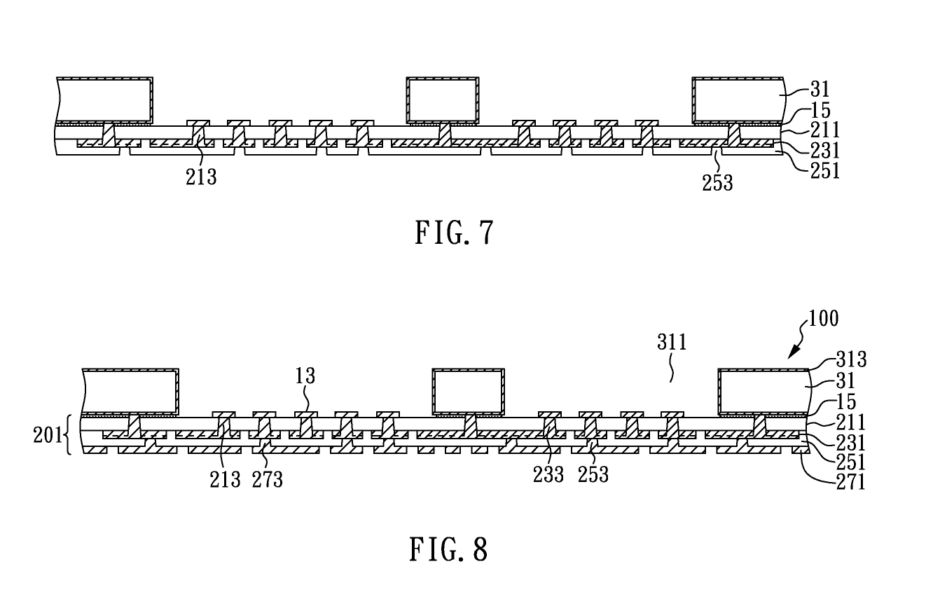

FIG. 7 is a cross-sectional view of the structure showing second via openings 253 formed through second dielectric layer 251 to expose selected portions of first conductive traces 231. Like first via openings 213, second via openings 253 can be formed by numerous techniques including laser drilling, plasma etching and photolithography and typically have a diameter of 50 microns. Preferably, first via openings 213 and second via openings 253 have the same size.

Referring now to FIG. 8, second conductive traces 271 are formed on second dielectric layer 251. Second conductive traces 271 extend from second dielectric layer 251 in the downward direction, extend laterally on second dielectric layer 251 and extend into second via openings 253 in the upward direction to form second conductive vias 273 in electrical contact with first conductive traces 231.

Second conductive traces 271 can be deposited as a conductive layer by numerous techniques including electrolytic plating, electroless plating, sputtering, and their combinations and then patterned by numerous techniques including wet etching, electro-chemical etching, laser-assist etching, and their combinations with an etch mask (not shown) thereon that defines second conductive traces 271. Preferably, first conductive traces 231 and second conductive traces 271 are the same material with the same thickness.

Accordingly, as shown in FIG. 8, multi-cavity wiring board 100 with internal EMI shield is accomplished and includes stiffener 31, adhesive 15 and coreless substrate 201. Stiffener 31 includes multiple apertures 311 with metallic sidewalls and is affixed on coreless substrate 201 using adhesive 15. Electrical pads 13 of coreless substrate 201 are exposed from apertures 311 of stiffener 31 in the upward direction, and the build-up circuitry of coreless substrate 201 is electrically connected to electrical pads 13 and conductive layer 313 of stiffener 31. In this illustration, the build-up circuitry includes first dielectric layer 211, first conductive traces 231, second dielectric layer 251 and second conductive traces 271. The signal routing can be provided by electrical pads 13, first conductive traces 231 and second conductive traces 271. The internal EMI shield of the wiring board can be provided by the metallic sidewalls of apertures 311 that are electrically connected to a portion of electrical pads 13 by first conductive vias 233 in contact with conductive layer 313 of stiffener 31 and electrical pads 13 for ground purpose.

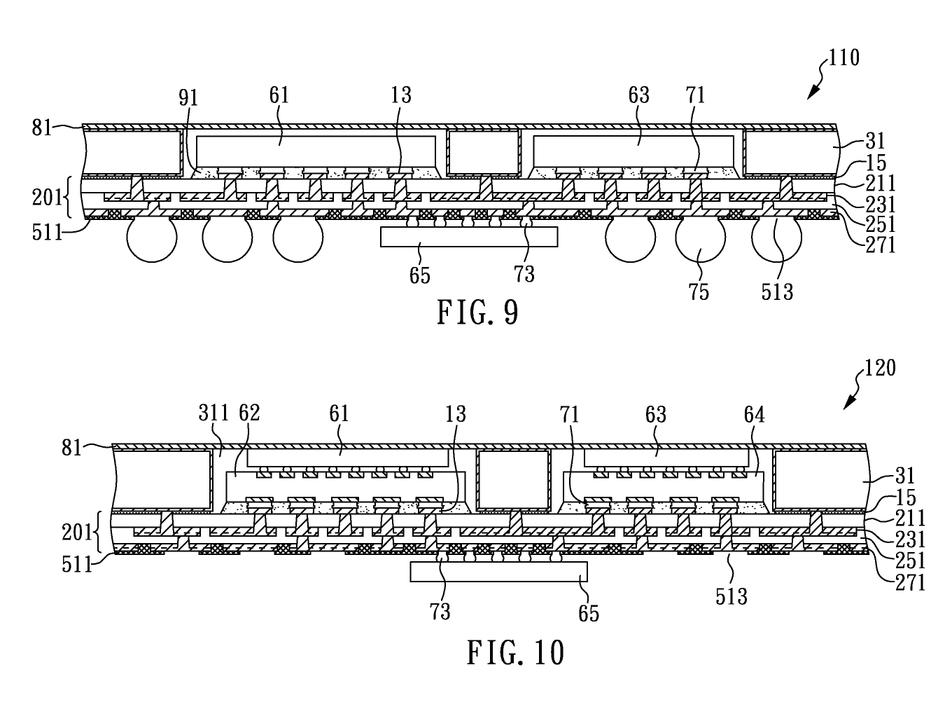

FIG. 9 is a cross-sectional view of a semiconductor assembly 110 in which semiconductor devices 61, 63 are electrically connected to coreless substrate 201 via solder bumps 71 on electrical pads 13. The signal contact pads of semiconductor devices 61, 63 are electrically connected to the signal transduction pathways of the wiring board that are provided by electrical pads 13, first conductive traces 231 and second conductive traces 271. The ground contact pads of semiconductor devices 61, 63 are electrically connected to conductive layer 313 of stiffener 31 through electrical pads 13 and first conductive traces 231. Further, metal lid 81 is attached onto stiffener 31 using adhesive and covers semiconductor devices 61, 63 in the upward direction. As a result, stiffener 31 and metal lid 81 can serve as lateral and vertical electromagnetic shields and diminish internal electromagnetic inference between semiconductor devices 61, 63. In this illustration, another semiconductor device 65 is further electrically coupled to coreless substrate 201 via solder bumps 73 on selected portions of second conductive traces 271. Also shown in FIG. 9 are solder mask material 511 over coreless substrate 201 and underfill 91 dispensed between semiconductor devices 61, 63 and coreless substrate 201. Selected portions of second conductive traces 271 are exposed from solder mask openings 513 to accommodate solder bumps 73 and solder balls 75. Through solder balls 75 on selected portions of second conductive traces 271, semiconductor assembly 110 can be further electrically connected with another assembly or external components.

FIG. 10 is a cross-sectional view of another semiconductor assembly 120 with interposers 62, 64 and semiconductor devices 61, 63 within apertures 311 of the wiring board. Interposers 62, 64 are electrically connected to coreless substrate 201 via solder bumps 71 on electrical pads 13, and semiconductor devices 61, 63 are flip mounted on interposers 62, 64. Interposers 62, 64 and coreless substrate 201 can provide signal routing for semiconductor devices 61, 63, and semiconductor devices 61, 63 can be shielded from EMI signals by metallic apertures 311 of stiffener 31 and metal lid 81.

### Embodiment 2

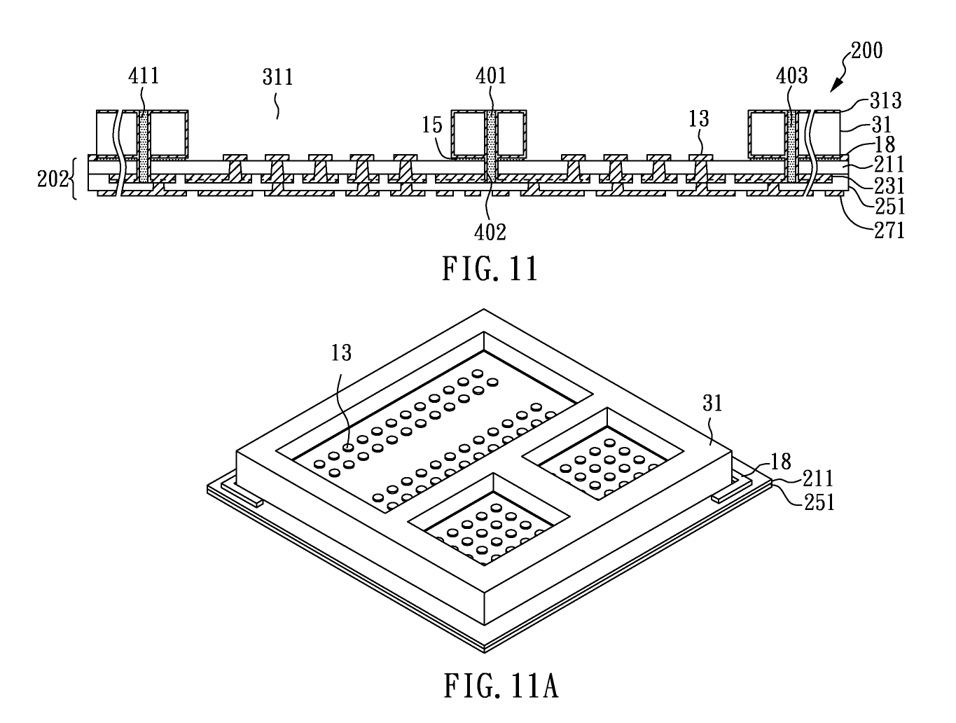

FIGS. 11 and 11A are cross-sectional and top views, respectively, of another multi-cavity wiring board 200 with plated through holes 411 as electrical connection between metallic sidewalls of apertures 311 and electrical pads 13 in accordance with another embodiment of the present invention.

In this embodiment, multi-cavity wiring board 200 is manufactured in a manner similar to that illustrated in Embodiment 1, except that the metallic sidewalls of apertures 311 are electrically connected to electrical pads 13 by first conductive traces 231 and plated through holes 411 that extend from conductive layer 313 on the top surface of stiffener 31 to first conductive traces 231 through stiffener 31, adhesive 15 and first dielectric layer 211 in vertical directions. Plated through holes 411 are formed by forming through holes 401 after attaching stiffener 31 and then depositing connecting layer 402 on the sidewall of through holes 401 during depositing first conductive traces 231. Through holes 401 are formed by mechanical drilling and can be formed by other techniques such as laser drilling and plasma etching with or without wet etching. In this illustration, connecting layer 402 is a hollow tube that covers the sidewall of through hole 401 in lateral directions and extends vertically to electrically connect conductive layer 313 of stiffener 31 to first conductive traces 231, and insulative filler 403 fills the remaining space in through hole 401. Alternatively, connecting layer 402 can fill through hole 401 in which case plated through hole 411 is a metal post and there is no space for an insulative filler in through hole 401.

Also shown in FIGS. 11 and 11A is placement guide 18 further formed on first dielectric layer 211. In this illustration, coreless substrate 202 includes electrical pads 13, placement guide 18, first dielectric layer 211, first conductive traces 231, second dielectric layer 251 and second conductive traces 271. Electrical pads 13 and placement guide 18 are simultaneously formed by removing selected portions of metal layer 11. In this embodiment, placement guide 18 is illustrated as a discontinuous strip and conforms to two diagonal corners of stiffener 31. However, placement guide 18 also can be designed into other various patterns against undesirable movement of stiffener 31. For instance, placement guide 18 also can consist of a continuous strip or plural metal posts, and can be in an arrangement that conforms to four sides, two diagonal corners or four corners of stiffener 31. As adhesive 15 under stiffener 31 is lower than placement guide 18, any undesirable movement of stiffener 31 due to adhesive curing can be avoided by placement guide 18 that is in close proximity to and laterally aligned with the peripheral edges of stiffener 31. Preferably, a gap in between placement guide 18 and the peripheral edges of stiffener 31 is in a range of about 0.001 to 1 mm. Accordingly, stiffener 31 can be precisely placed at a predetermined location by placement guide 18 that extends from first dielectric layer 211 beyond the attached surface of stiffener 31 in the upward direction and laterally extends beyond the peripheral edges of stiffener 31 in the lateral directions. Nevertheless, placement guide 18 is not indispensable but is favorable for placement accuracy of stiffener 31.

### Embodiment 3

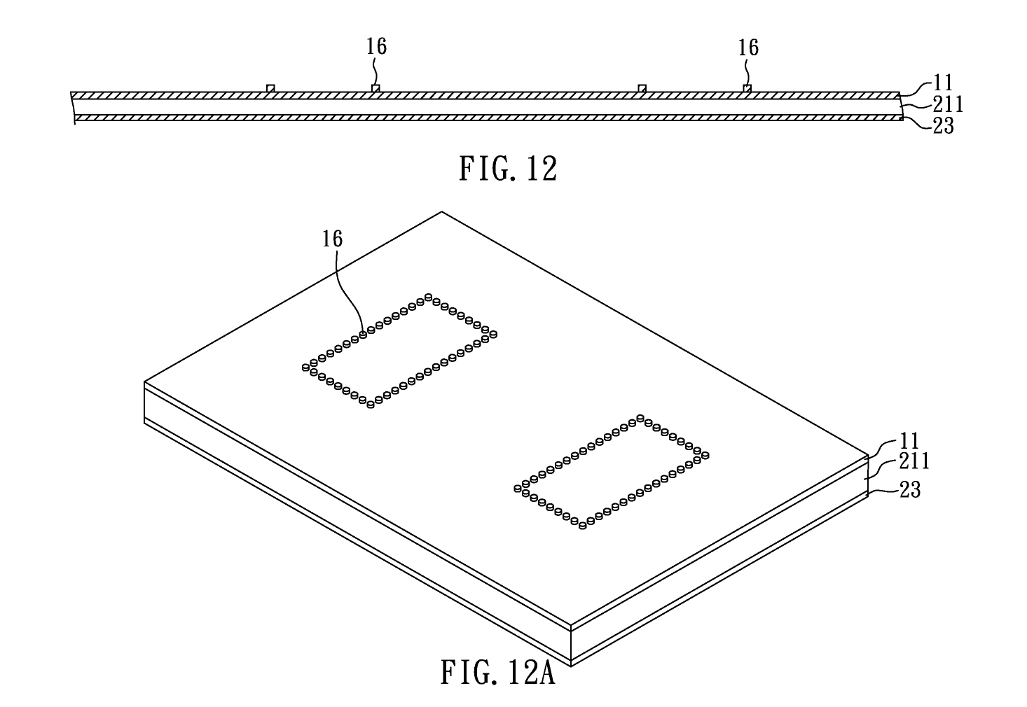

FIGS. 12-18 are cross-section views showing a method of making yet another multi-cavity wiring board with electrical pads, thermal paddles, stoppers and placement guide exposed from metallic apertures of a stiffener in accordance with yet another embodiment of the present invention.

For purposes of brevity, any description in above Embodiments is incorporated herein insofar as the same is applicable, and the same description need not be repeated.

FIGS. 12 and 12A are cross-sectional and top views, respectively, of the structure with stoppers 16 formed on metal layer 11 of laminate substrate. As illustrated in above embodiments, the laminate substrate includes metal layer 11, first dielectric layer 211 and support plate 23. Stoppers 16 can be formed by electrolytic plating of metal on metal layer 11 using photolithographic process. In this illustration, each stopper 16 consists of plural metal posts in a rectangular frame array with a thickness of 35 microns and conforms to four sides of a semiconductor device subsequently disposed on metal layer 11. However, stopper patterns are not limited thereto and can be other various patterns against undesirable movement of the subsequently disposed semiconductor device. For instance, stopper 16 also can consist of a continuous or discontinuous strip, and can be in an arrangement that conforms to four sides, two diagonal corners or four corners of a subsequently disposed interposer and stiffener. In addition, stoppers 16 are not indispensable but favorable for subsequent placement accuracy of semiconductor devices.

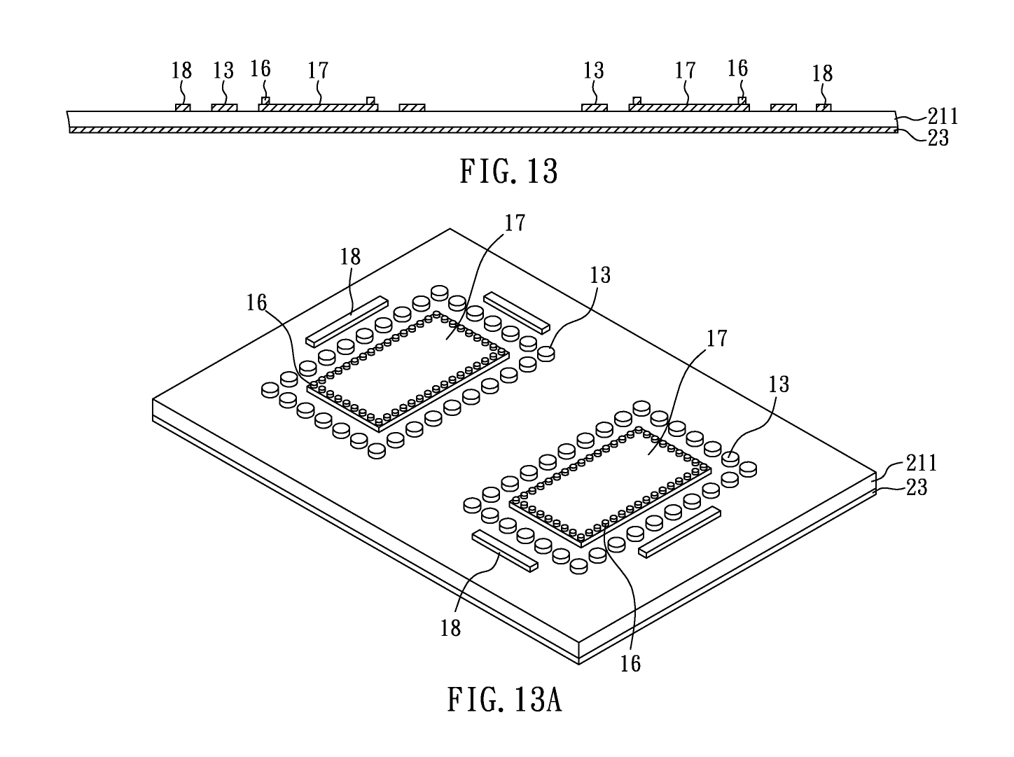

FIGS. 13 and 13A are cross-sectional and top views, respectively, of the structure with electrical pads 13, thermal paddles 17 and placement guide 18 formed on first dielectric layer 211. Electrical pads 13, thermal paddles 17 and placement guide 18 can be formed by removing selected portions of metal layer 11 using photolithography and wet etching. Each thermal paddle 17 corresponds to the predetermined location for placing a semiconductor device and can serve as a heat spreader. Further, as shown in FIG. 13A, placement guide 18 is illustrated as a discontinuous strip and conforms to four aperture sidewalls of a stiffener subsequently disposed on first dielectric layer 211. As mentioned for stoppers 16, placement guide 18 can also be designed into various patterns against undesirable movement of the subsequently disposed stiffener. It is also adopted to omit placement guide 18, but placement guide 18 is favorable for subsequent placement accuracy of stiffener.

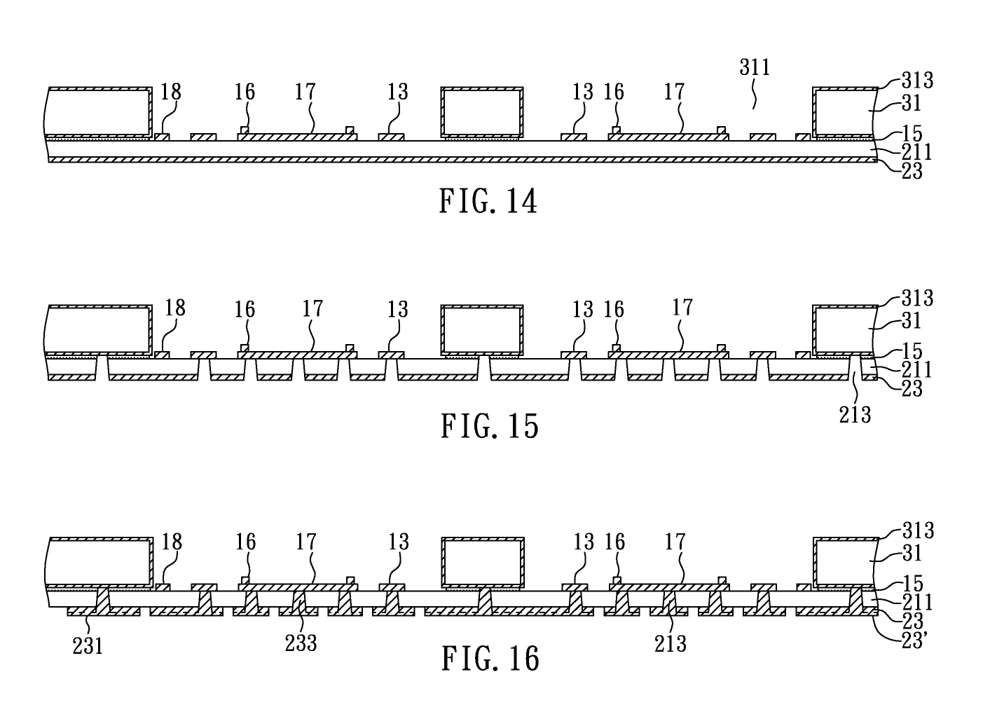

FIG. 14 is a cross-section view of the structure with stiffener 31 mounted onto first dielectric layer 211. Electrical pads 13, thermal paddles 17 and placement guide 18 are aligned with apertures 311 of stiffener 31, and stiffener 31 is mounted on first dielectric layer 211 using adhesive 15. Stiffener 31 can be precisely placed at a predetermined location by placement guide 18 that extends from first dielectric layer 211 beyond the attached surface of stiffener 31 in the upward direction and laterally extend between electrical pads 13 and the metallic sidewalls of apertures 311 in the lateral directions. As adhesive 15 under stiffener 31 is lower than placement guide 18, any undesirable movement of stiffener 31 due to adhesive curing can be avoided by placement guide 18 that is in close proximity to and laterally aligned with and conforms to four aperture sidewalls of stiffener 31 in lateral directions. Preferably, a gap in between placement guide 18 and the metallic sidewalls of apertures 311 is in a range of about 0.001 to 1 mm.

FIG. 15 is a cross-sectional view of the structure provided with first via openings 213. First via openings 213 extend through support plate 23, first dielectric layer 211 and adhesive 15 to expose selected portions of electrical pads 13, thermal paddles 17 and conductive layer 313 of stiffener 31 in the downward direction.

Referring now to FIG. 16, first conductive traces 231 are formed on first dielectric layer 211 by depositing plated layer 23′ on support plate 23 and into first via openings 213 and then patterning support plate 23 and plated layer 23′ thereon. First conductive traces 231 extend from first dielectric layer 211 in the downward direction, extend laterally on first dielectric layer 211 and extend into first via openings 213 in the upward direction to form first conductive vias 233 in contact with electrical pads 13, thermal paddles 17 and conductive layer 313 of stiffener 31. Accordingly, first conductive traces 231 can provide signal routing and ground connection through first conductive vias 233 in contact with electrical pads 13 and conductive layer 313 of stiffener. Also, first conductive traces 231 can provide thermal connection through first conductive vias 233 in contact with thermal paddles 17.

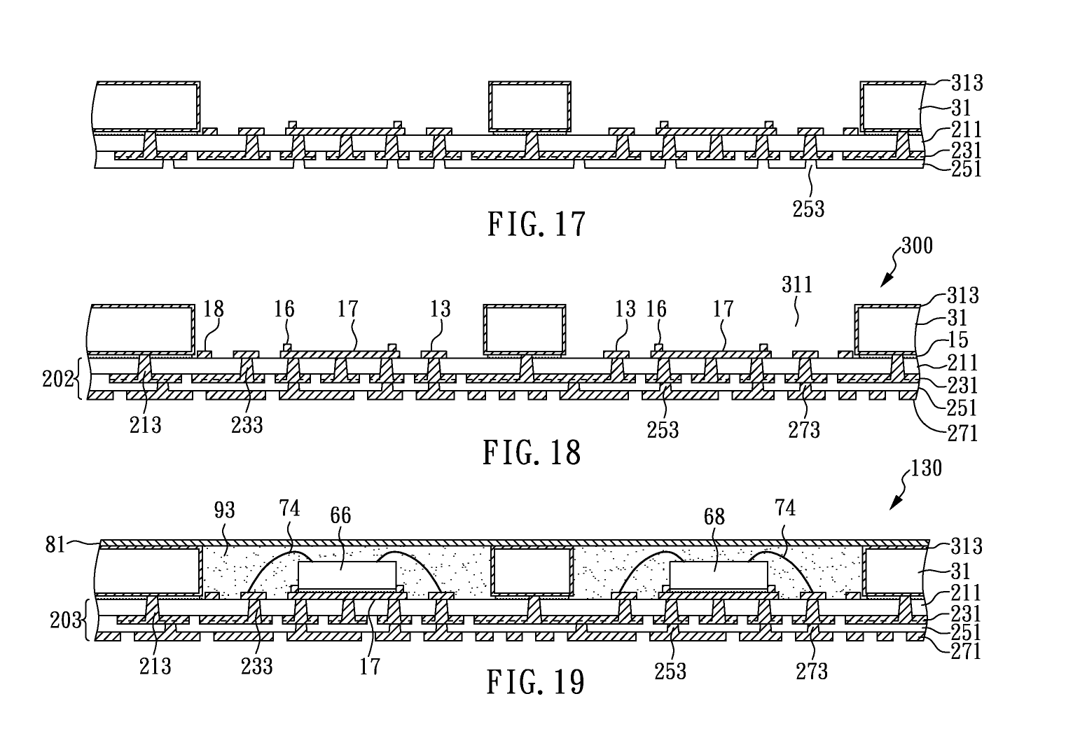

FIG. 17 is a cross-sectional view of the structure showing second dielectric layer 251 with second via openings 253 on first conductive traces 231 and first dielectric layer 211. Second via openings 253 extend through second dielectric layer 251 to expose selected portions of first conductive traces 231.

Referring now to FIG. 18, second conductive traces 271 are formed on second dielectric layer 251. Second conductive traces 271 extend from second dielectric layer 251 in the downward direction, extend laterally on second dielectric layer 251 and extend into second via openings 253 in the upward direction to form second conductive vias 273 in electrical contact with first conductive traces 231.

Accordingly, as shown in FIG. 18, multi-cavity wiring board 300 is accomplished and includes electrical pads 13, stoppers 16, thermal paddles 17 and placement guide 18 exposed from metallic apertures 311 of stiffener 31 that is affixed on coreless substrate 203 using adhesive 15. In this illustration, the build-up circuitry of coreless substrate 203 includes first dielectric layer 211, first conductive traces 231, second dielectric layer 251 and second conductive traces 271. First conductive traces 231 extend through first via openings 213 to form first conductive traces 233 in contact with electrical pads 13, thermal paddles 17 and conductive layer 313 of stiffener 31. The signal routing of multi-cavity wiring board 300 is provided by electrical pads 13, first conductive traces 231 and second conductive traces 271. The thermal conduction pathway of multi-cavity wiring board 300 is provided by thermal paddles 17, first conductive traces 231 and second conductive traces 271. Further, the electrical connection between electrical pads 13 and conductive layer 313 of stiffener 31 is provided by first conductive traces 231 for ground connection purpose. Accordingly, the metallic sidewalls of apertures 311 of stiffener 31 can provide effective lateral EMI shielding for semiconductor devices mounted within apertures 311.

FIG. 19 is a cross-sectional view of a semiconductor assembly 130 in which semiconductor devices 66, 68 are mounted on thermal paddles 17 using adhesive and electrically connected to electrical pads 13 via wire bonds 74. Stoppers 16 can serve as a placement guide for semiconductor devices 66, 68, and thus semiconductor devices 66, 68 are precisely placed at a predetermined location. Stoppers 16 extend from thermal paddles 17 beyond the attached surface of semiconductor devices 66, 68 in the upward direction and are laterally aligned with and laterally extend beyond four sides of semiconductor devices 66, 68 in the lateral directions. As adhesive under semiconductor devices 66, 68 is lower than stoppers 16, any undesirable movement of semiconductor devices 66, 68 due to adhesive curing can be avoided by stoppers 16 that are in close proximity to and conforms to four lateral surfaces of semiconductor devices 66, 68 in lateral directions. Preferably, a gap in between semiconductor devices 66, 68 and stoppers 16 is in a range of about 0.001 to 1 mm. Further, metal lid 81 is attached onto stiffener 31 using adhesive and covers semiconductor devices 66, 68 in the upward direction. As a result, metallic sidewalls of apertures 311 and metal lid 81 can serve as lateral and vertical electromagnetic shields and diminish internal electromagnetic interference between semiconductor devices 66, 68. Also shown in FIG. 19 is encapsulant 93 dispensed within apertures to protect semiconductor devices 66, 68 and wire bonds 74.

The wiring boards and semiconductor assemblies described above are merely exemplary. Numerous other embodiments are contemplated. In addition, the embodiments described above can be mixed-and-matched with one another and with, other embodiments depending on design and reliability considerations.

The semiconductor device can be a packaged or unpackaged chip. Furthermore, the semiconductor device can be a bare chip, or a wafer level packaged die, etc. The semiconductor devices can be mechanically and electrically connected to the coreless substrate using a wide variety of connection media including gold or solder bumps, bonding wires. Each aperture of the stiffener can be customized to accommodate a single semiconductor device. For instance, each aperture can have a square or rectangular shape with the same or similar topography and dimension as a single semiconductor device. Likewise, each thermal paddle also can be customized to have a shape with the same or similar topography as a single semiconductor device.

The term “adjacent” refers to elements that are integral (single-piece) or in contact (not spaced or separated from) with one another. For instance, the electrical pads are adjacent to the first conductive traces, but not adjacent to the second conductive traces.

The term “overlap” refers to above and extending within a periphery of an underlying element. Overlap includes extending inside and outside the periphery or residing within the periphery. For instance, in the position that the build-up circuitry faces the upward direction, the build-up circuitry overlaps the stiffener since an imaginary vertical line intersects the build-up circuitry and the stiffener, regardless of whether another element such as the adhesive is between the build-up circuitry and thestiffener and is intersected by the line, and regardless of whether another imaginary vertical line intersects the build-up circuitry but not the stiffener (within the apertures of the stiffener). Likewise, the build-up circuitry overlaps the electrical pads and the electrical pads are overlapped by the build-up circuitry. Moreover, overlap is synonymous with over and overlapped by is synonymous with under or beneath.

The term “contact” refers to direct contact. For instance, the adhesive contacts the first dielectric layer but does not contact the second dielectric layer.

The term “cover” refers to incomplete and complete coverage in a vertical and/or lateral direction. For instance, in the position that the build-up circuitry faces the upward direction, the build-up circuitry covers the stiffener in the upward direction regardless of whether another element such as the adhesive is between the stiffener and the build-up circuitry.

The term “layer” refers to patterned and un-patterned layers. For instance, the metal layer disposed on the dielectric layer can be an un-patterned blanket sheet before photolithography and wet etching. Furthermore, a layer can include stacked layers.

The terms “opening”, “aperture” and “hole” refer to a through hole and are synonymous. For instance, in the position that the build-up circuitry faces the downward direction, the electrical, pads are exposed by the apertures of the stiffener in the upward direction.

The phrase “aligned with” refers to relative position between elements regardless of whether elements are spaced from or adjacent to one another or one element is inserted into and extends into the other element. For instance, the placement guide is laterally aligned with the stiffener since an imaginary horizontal line intersects the placement guide and the stiffener, regardless of whether another element is between the placement guide and the stiffener and is intersected by the line, and regardless of whether another imaginary horizontal line intersects the stiffener but not the placement guide or intersects the placement guide but not the stiffener. Likewise, the first via openings are aligned with the electrical pads, and the electrical pads are aligned with the apertures.

The phrase “in close proximity to” refers to a gap between elements not being wider than the maximum acceptable limit. As known in the art, when the gap between the stiffener and the placement guide is not narrow enough, the location error of the stiffener due to the lateral displacement of the stiffener within the gap may exceed the maximum acceptable error limit. In some cases, once the location error of the stiffener goes beyond the maximum limit, it is impossible to align the predetermined portion of the stiffener with a laser beam, resulting in the electrical connection failure between the stiffener and the build-up circuitry. According to the dimension of the predetermined connection portion of the stiffener, those skilled in the art can ascertain the maximum acceptable limit for a gap between the stiffener and the placement guide through trial and error to ensure the conductive vias being aligned with the predetermined connection portion of the stiffener. Thereby, the descriptions “the placement guide is in close proximity to the peripheral edges of the stiffener”, “the placement guide is in close proximity to the aperture sidewalls of the stiffener” and “the stopper is in close proximity to the peripheral edges of the semiconductor device” mean that the gap between them is narrow enough to prevent the location error of the stiffener or the semiconductor device from exceeding the maximum acceptable error limit.

The phrase “mounted on” includes contact and non-contact with a single or multiple support element(s). For instance, the semiconductor devices are mounted on the thermal paddles regardless of whether they contact the thermal paddles or are separated from the thermal paddles by an adhesive.

The phrase “electrical connection” or “electrically connects” or “electrically connected” refers to direct and indirect electrical connection. For instance, the first conductive trace provides an electrical connection between the terminal pad and the electrical pads regardless of whether the first conductive trace is adjacent to the terminal pad or electrically connected to the terminal pad by the second conductive trace.

The term “above” refers to upward extension and includes adjacent and non-adjacent elements as well as overlapping and non-overlapping elements. For instance, in the position that the build-up circuitry faces the downward direction, the placement guide extends above, is adjacent to and protrudes from the first dielectric layer.

The term “below” refers to downward extension and includes adjacent and non-adjacent elements as well as overlapping and non-overlapping elements. For instance, in the position that the build-up circuitry faces the downward direction, the build-up circuitry extends below the stiffener in the downward direction regardless of whether the build-up circuitry is adjacent to the stiffener.

The “first vertical direction” and “second vertical direction” do not depend on the orientation of the wiring board, as will be readily apparent to those skilled in the art. For, instance, the build-up circuitry covers the stiffener in the first vertical direction and the electrical pads are exposed from the apertures in the second vertical direction regardless of whether the wiring board is inverted. Likewise, the placement guide is “laterally” aligned with the stiffener in a lateral plane regardless of whether the wiring board is inverted, rotated or slanted. Thus, the first and second vertical directions are opposite one another and orthogonal to the lateral directions, and a lateral plane orthogonal to the first and second vertical directions intersects laterally aligned elements. Furthermore, the first vertical direction is the downward direction and the second vertical direction is the upward direction in the position that the build-up circuitry faces the downward direction, and the first vertical direction is the upward direction and the second vertical direction is the downward direction in the position that the build-up circuitry faces the upward direction.

The wiring board and the semiconductor assembly using the same according to the present invention have numerous advantages. The wiring board and the semiconductor assembly are reliable, inexpensive and well-suited for high volume manufacture. The lateral shielding sidewalls of the stiffener can serve as lateral EMI shields for semiconductor devices within the apertures and therefore are favorable for multi-chip package with minimized internal electromagnetic interference. The signal routing provided by the build-up circuitry is advantageous for high I/O and high performance applications due to the high routing capability of the build-up circuitry. The stiffener can provide a mechanical support for the coreless substrate and electronic devices packaged in the wiring board. The placement location of the stiffener can be accurately confined by the placement guide to avoid the undesired lateral displacement of the stiffener, thereby improving the manufacturing yield greatly. The wiring board and the semiconductor assembly using the same are reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

Various changes and modifications to the embodiments described herein will be apparent to those skilled in the art. For instance, the materials, dimensions, shapes, sizes, steps and arrangement of steps described above are merely exemplary. Such changes, modifications and equivalents may be made without departing from the spirit and scope of the present invention as defined in the appended claims.

Although the present invention has been explained in relation to its preferred embodiment, it is to be understood that many other possible modifications and variations can be made without departing from the spirit and scope of the invention as hereinafter claimed.

What is claimed is:

1. A multi-cavity wiring board for a semiconductor assembly with electromagnetic shielding, comprising:
a stiffener that includes a plurality of apertures with lateral shielding sidewalls;
a coreless substrate that covers the stiffener in a first vertical direction and includes electrical pads and a build-up circuitry, wherein (i) the electrical pads are aligned with and exposed from the apertures in a second vertical direction opposite the first vertical direction, (ii) the build-up circuitry covers the electrical pads and the stiffener in the first vertical direction and is electrically connected to the electrical pads through first conductive vias, and (iii) the stiffener is electrically connected to a portion of the electrical pads for grounding the lateral shielding sidewalls through the build-up circuitry; and
an adhesive that contacts and is sandwiched between the stiffener and the coreless substrate.

2. The multi-cavity wiring board of claim 1, wherein the stiffener is electrically connected to the build-up circuitry through an additional first conductive via of the build-up circuitry.

3. The multi-cavity wiring board of claim 1, wherein the stiffener is electrically connected to the build-up circuitry through a plated through-hole that extends through the stiffener.

4. The multi-cavity wiring board of claim 1, wherein the coreless substrate further includes a placement guide that extends from the build-up circuitry in the second vertical direction and laterally extends beyond the peripheral edges of the stiffener.

5. The multi-cavity wiring board of claim 1, wherein the coreless substrate further includes at least one thermal paddle that is covered by the build-up circuitry in the first vertical direction and is exposed from the aperture of the stiffener in the second vertical direction.

6. The multi-cavity wiring board of claim 5, wherein the build-up circuitry includes an additional first conductive via that directly contacts the thermal paddle.

7. The multi-cavity wiring board of claim 1, further comprising an interposer that extends into on of the apertures of the stiffener and is electrically connected to the coreless substrate.
